(19) United States
(12) Patent Application Publication
(10) Pub. No.: US 2026/0311956 A1
(43) Pub. Date: Oct. 8, 2026

(54) CORRECTING FOR GRID DISTORTION

(71) Applicant: ASML Netherlands B.V., Veldhoven (NL)

(72) Inventors: Jasper Frans Mathijs VAN RENS, Hegelsom (NL); Maikel Robert GOOSEN, Eindhoven (NL)

(73) Assignee: ASML Netherlands B.V., Veldhoven (NL)

(21) Appl. No.: 19/481,360

(22) PCT Filed: Apr. 4, 2024
(86) PCT No.: PCT/EP2024/059270

§ 371 Date: Nov. 4, 2025

(30) Foreign Application Priority Data
May 4, 2023 (EP) 23171511.1

(51) Int. Cl. H01J 37/153; H01J 37/28

(52) U.S. Cl. CPC H01J 37/153; H01J 37/28; H01J 2237/1534; H01J 2237/1536

(57) ABSTRACT

A method for operating a charged particle-optical apparatus, the method comprising: scanning, with the charged particle-optical apparatus, a sample comprising a series of locations with a charged particle beam, so as to generate scan data; changing a setting of at least one charged particle-optical parameter of the charged particle-optical apparatus from location to location, wherein the at least one charged particle-optical parameter affects a charged particle-optical grid distortion of the scan data; and compensating for the charged particle-optical grid distortion, based on the changed setting of the at least one charged particle-optical parameter.

### CROSS-REFERENCE TO RELATED APPLICATION

This application claims priority of an EP application No. 23171511.1 which was filed on 4 May 2023, and which is incorporated herein in its entirety by reference.

### TECHNICAL FIELD

The embodiments provided herein disclose a method of operating a charged particle-optical apparatus, a charged particle-optical apparatus, a non-transitory computer readable medium, a method of operating a scanning electron microscope (SEM) and a scanning electron microscope.

### BACKGROUND

In manufacturing processes of integrated circuits (ICs), unfinished or finished circuit components are assessed to ensure that they are manufactured according to design and are free of defects. Assessment (e.g. metrology or inspection) systems utilizing optical microscopes or charged particle (e.g., electron) beam microscopes, such as a SEM can be employed. As the physical sizes of IC components continue to shrink, and their structures continue to become more complex, accuracy and throughput in assessment (e.g. metrology or defect detection and inspection) become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as critical dimension, periodicity and placement error metrology, it may be desirable to obtain high quality imaging and efficient collection of surface information from secondary electrons and buried layer information from backscattered electrons, simultaneously, highlighting a need for using multiple electron detectors in a SEM. Although multiple electron detectors in various structural arrangements may be used to maximize collection and detection efficiencies of secondary and backscattered electrons individually, the combined detection efficiencies remain low, and therefore, the image quality achieved may be inadequate for high accuracy and high throughput assessment of two-dimensional and three-dimensional structures.

### SUMMARY

An embodiment of the present disclosure provides a method for operating a charged particle-optical apparatus, the method comprising: scanning, with the charged particle-optical apparatus, a sample comprising a series of locations with a charged particle beam, so as to generate scan data; changing a setting of at least one charged particle-optical parameter of the charged particle-optical apparatus from location to location, wherein the at least one charged particle-optical parameter affects a charged particle-optical grid distortion of the scan data; and compensating for the charged particle-optical grid distortion, based on the changed setting of the at least one charged particle-optical parameter.

An embodiment of the present disclosure provides a charged particle-optical apparatus for scanning a sample comprising a series of locations with a charged particle beam, so as to generate scan data, the charged particle-optical apparatus comprising: a charged particle-optical device configured to direct a charged particle beam onto a series of locations, in turn; a detector configured to detect signal charged particles emitted from the locations, so as to generate scan data; and a controller configured to: change a setting of at least one charged particle-optical parameter of the charged particle-optical apparatus from location to location, wherein the at least one charged particle-optical parameter affects a charged particle-optical grid distortion of the scan data; and compensate for the charged particle-optical grid distortion, based on the changed setting of the at least one charged particle-optical parameter.

An embodiment of the present disclosure provides a non-transitory computer readable medium that stores instructions for a processor of a controller to carry out a method of operating a charged particle-optical apparatus, the method comprising: scanning, with the charged particle-optical apparatus, a sample comprising a series of dies locations with a charged particle beam, so as to generate scan data; changing a setting of at least one charged particle-optical parameter of the charged particle-optical apparatus from die location to dielocation, wherein the at least one charged particle-optical parameter affects a charged particle-optical grid distortion of the scan data; and compensating for the charged particle-optical grid distortion, based on the changed setting of the at least one charged particle-optical parameter.

An embodiment of the present disclosure provides a method for operating a scanning electron microscope, SEM, the method comprising: scanning, with the SEM, a sample comprising a series of dies locations with an electron beam, so as to generate scan data; changing a setting of at least one electron-optical parameter of the SEM from die location to dielocation, wherein the at least one electron-optical parameter affects an electron-optical grid distortion of the scan data; and compensating for the electron-optical grid distortion, based on the changed setting of the at least one electron-optical parameter.

An embodiment of the present disclosure provides a scanning electron microscope, SEM, for scanning a sample comprising a series of dies locations with an electron beam, so as to generate scan data, the SEM comprising: an electron-optical device configured to direct an electron beam onto a sample comprising a series of dieslocations, in turn; a detector configured to detect signal electrons emitted from the dieslocations, so as to generate scan data; and a controller configured to: change a setting of at least one electron-optical parameter of the SEM from die location to dielocation, wherein the at least one electron-optical parameter affects an electron-optical grid distortion of the scan data; and compensate for the electron-optical grid distortion, based on the changed setting of the at least one electron-optical parameter.

An embodiment of the present disclosure provides a non-transitory computer readable medium that stores instructions for a processor of a controller to carry out a method of operating a scanning electron microscope, SEM, the method comprising: scanning, with the SEM, a sample comprising a series of dies locations with an electron beam, so as to generate scan data; changing a setting of at least one electron-optical parameter of the SEM from die location to dielocation, wherein the at least one electron-optical parameter affects an electron-optical grid distortion of the scan data; and compensating for the electron-optical grid distortion, based on the changed setting of the at least one electron-optical parameter.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings in which:

FIG. 1 is a schematic diagram illustrating an exemplary electron beam assessment system, consistent with embodiments of the present disclosure.

FIG. 2A, FIG. 2B, and FIG. 2C are schematic diagrams illustrating exemplary electron beam tools, consistent with embodiments of the present disclosure that may be a part of the exemplary electron beam assessment system of FIG. 1.

FIG. 3 is a diagram illustrating a grid distortion associated with scan data generated by an electron-optical apparatus.

FIG. 4 is a diagram illustrating a translational contribution to the grid distortion.

FIG. 5 is a diagram illustrating a rotational contribution to the grid distortion.

FIG. 6 is a diagram illustrating a magnification contribution to the grid distortion.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied.

One component of improving yield is monitoring the chip making process to ensure that it is producing a sufficient number of functional integrated circuits. One way to monitor the process is to assess the chip circuit structures at various stages of their formation. Assessment can be carried out using an SEM. An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. It may be desirable to have higher throughput for defect detection and assessment processes to meet the requirements of IC manufacturers.

The image may be distorted such that structures in the image are positioned differently compared to on the actual chip circuit. The image may be translated (i.e. shifted in the image plane), rotated, magnified and/or deformed by a higher order distortion compared to the actual chip circuit. Some of the distortion is caused by the SEM and it is desirable to correct for this. Some of the SEM-induced distortion can be corrected using a model that takes into account information about the type of structures expected to be on the chip circuits. The same model can be used across different chips. In order to improve correction for the SEM-induced distortion, settings, for example electron-optical settings, of the SEM that are changed from location to location (on the wafer) can be taken into account. These settings are not accounted for by the model that is used across different chips, because while the model remains the same, the SEM settings do not. By taking into account the location-dependent settings, the distortion can be better corrected for.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

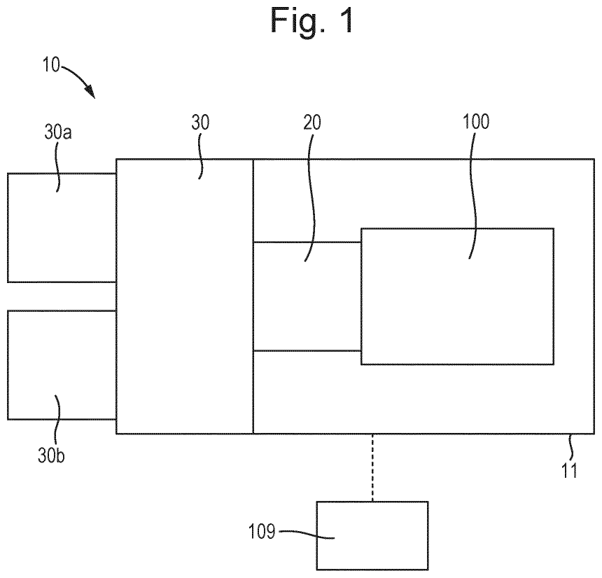

Reference is now made to FIG. 1, which illustrates an exemplary electron beam assessment system 10 that may include a detector, consistent with embodiments of the present disclosure. assessment system 10 may be used for imaging. As shown in FIG. 1, the assessment system 10 includes a main chamber 11 a load/lock chamber 20, an electron beam tool 100, and an equipment front end module (EFEM) 30. Electron beam tool 100 is located within main chamber 11. EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be assessed (wafers and samples may be collectively referred to as “samples” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to assessment by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of the assessment system 10. While controller 109 is shown in FIG. 1 as being outside of the structure that includes main chamber 11, load/lock chamber 20, and EFEM 30, it is appreciated that controller 109 can be part of the structure.

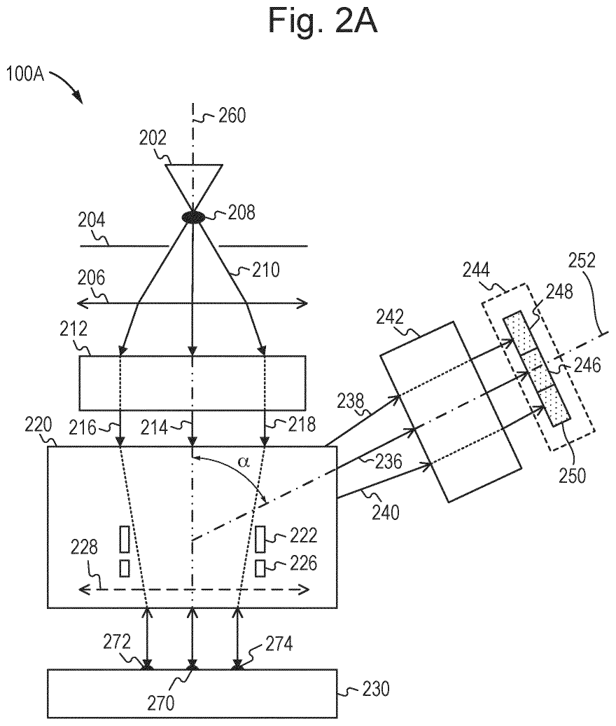

FIG. 2A illustrates a charged particle beam apparatus in which an assessment system may comprise a multi-beam assessment tool that uses multiple primary electron beamlets to simultaneously scan multiple locations on a sample.

As shown in FIG. 2A, an electron beam tool 100A (also referred to herein as an electron beam apparatus 100A or an electron-optical device) may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and an electron detection device 244. Electron source 202 may generate primary particles, such as electrons of primary electron beam 210. A controller, image processing system, and the like may be coupled to electron detection device 244. Primary projection optical system 220 may comprise a beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of electron beam apparatus 100A. Secondary optical system 242 and electron detection device 244 may be aligned with a secondary optical axis 252 of electron beam apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be a moveable condenser lens that may be configured so that the position of its first principle plane is movable. The movable condenser lens may be configured to be magnetic, which may result in off-axis beamlets 216 and 218 landing on the beamlet-limit apertures with rotation angles. The rotation angles change with the focusing power and the position of the first principal plane of the movable condenser lens. In some embodiments, the moveable condenser lens may be a moveable anti-rotation condenser lens, which involves an anti-rotation lens with a movable first principal plane. A moveable condenser lens is further described in U.S. Publication No. 2017/0025241, which is incorporated by reference in its entirety.

Objective lens 228 may focus beamlets 214, 216, and 218 onto a wafer 230 (i.e. a sample) for assessment and may form a plurality of probe spots 270, 272, and 274 on the surface of wafer 230.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over a surface area of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of surface area of wafer 230.

Although FIG. 2A shows an example of electron beam tool 100 as a multi-beam tool that uses a plurality of beamlets, embodiments of the present disclosure are not so limited. For example, electron beam tool 100 may also be a single-beam tool that uses only one primary electron beam to scan one location on a wafer at a time.

As shown in FIG. 2B, an electron beam tool 100B (also referred to herein as electron beam apparatus 100B) may be a single-beam assessment tool that is used in the assessment system 10. Electron beam apparatus 100B includes an electron-optical device configured to project electrons towards a sample location (i.e. where the wafer is) and a wafer holder 136 supported by motorized stage 134 to hold a wafer 150 (i.e. a sample) to be assessed. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, Internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an assessment system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. However, some embodiments may use a detector placed off-axis relative to the optical axis along which the primary electron beam travels. For example, as in the embodiment shown in FIG. 2A, beam separator 222 may be provided to direct secondary electron beams toward a detector placed off-axis. Beam separator 222 may be configured to divert secondary electron beams by an angle a.

Another example of a charged particle beam apparatus will now be discussed with reference to FIG. 2C. Electron beam tool 100C (also referred to herein as an electron beam apparatus 100C or an electron-optical device) may be an example of electron beam tool 100 and may be similar to electron beam tool 100A shown in FIG. 2A.

As shown in FIG. 2C, beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. For a dispersion plane 224 of beam separator 222, FIG. 2C shows dispersion of beamlet 214 with nominal energy V0 and an energy spread AV into beamlet portions 262 corresponding to energy V0, beamlet portion 264 corresponding to energy V0+ΔV/2, and beamlet portion 266 corresponding to energy V0−ΔV/2. The total force exerted by beam separator 222 on an electron of secondary electron beams 236, 238, and 240 can be non-zero. Beam separator 222 may separate secondary electron beams 236, 238, and 240 from beamlets 214, 216, and 218 and direct secondary electron beams 236, 238, and 240 towards secondary optical system 242.

A semiconductor electron detector (sometimes called a “PIN detector”) may be used in apparatus 100 in the assessment system 10. The assessment system 10 may be a high-speed wafer imaging SEM including an image processor. An electron beam generated by the assessment system 10 may irradiate the surface of a sample or may penetrate the sample. The assessment system 10 may be used to image a sample surface or structures under the surface, such as for analyzing layer alignment. In some embodiments, the assessment system 10 may detect and report process defects relating to manufacturing semiconductor wafers by, for example, comparing SEM images against device layout patterns, or SEM images of identical patterns at other locations on the wafer under assessment. A PIN detector may include a silicon PIN diode that may operate with negative bias. A PIN detector may be configured so that incoming electrons generate a relatively large and distinct detection signal. In some embodiments, a PIN detector may be configured so that an incoming electron may generate a number of electron-hole pairs while a photon may generate just one electron-hole pair. A PIN detector used for electron counting may have numerous differences as compared to a photodiode used for photon detection, as shall be discussed as follows.

In an embodiment the detector (e.g. the electron detection device 244 shown in FIG. 2A or FIG. 2C or the detector 144 shown in FIG. 2B) comprises a plurality of detector elements (e.g. detection sub-regions 246, 248, and 250). The detector elements may be connected to one or more circuit layers. A circuit layer of the detector may comprise circuitry having amplification and/or digitation functions, e.g. it may comprise a amplification circuit. A circuit layer may comprise one or more trans impedance amplifiers (TIAs) and one or more ADCs. A detector element and an associated feedback resistor may be connected to the TIA and ADC. One or more digital signal lines may be connected from the ADC for transferring digital signals, e.g. to the image acquirer 120 shown in FIG. 2B.

In some embodiments, a detector may communicate with a controller that controls a charged particle beam system. The controller may instruct components of the charged particle beam system to perform various functions, such as controlling a charged particle source to generate a charged particle beam and controlling a deflector to scan the charged particle beam. The controller may also perform various other functions such as adjusting a sampling rate of a detector, resetting a sensing element, or performing image processing. In an embodiment the controller is configured to control settings of the ADCs. The controller may comprise a storage that is a storage medium such as a hard disk, random access memory (RAM), other types of computer readable memory, and the like. The storage may be used for saving scanned raw image data as original images, and post-processed images. A non-transitory computer readable medium may be provided that stores instructions for a processor of controller 109 to carry out charged particle beam detection, sampling period determination, image processing, or other functions and methods consistent with the present disclosure. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a ROM, a PROM, and EPROM, a FLASH-EPROM or any other flash memory, NVRAM, a cache, a register, any other memory chip or cartridge, and networked versions of the same.

An electron beam apparatus 100, such as is shown in FIG. 2A, FIG. 2B or FIG. 2C may scan a sample with one or more electron beams. The electron beam apparatus 100 is configured to detect signal electrons emitted from the sample so as to generate scan data. The scan data may be image data. An image may be generated from the scan data. The scan data may be data of currents of signal electrons emitted from different locations of the sample. The electron beam apparatus 100 may be embodied as an SEM. The scan data may be SEM image data.

A sample (e.g. a substrate or wafer) may comprise a plurality of dies. A chip circuit may be fabricated on a die. A plurality of dies of a sample may comprise the same chip circuit.

In an embodiment a method is for operating an electron beam apparatus 100 (which may also be referred to as an electron-optical apparatus or a charged particle-optical apparatus). In an embodiment the method comprises scanning, with the electron beam apparatus 100, a sample (e.g. a semiconductor wafer) comprising a series (e.g. an array) of locations (e.g. dies) with an electron beam. The locations may be part of the same sample. Alternatively, some of the locations may be part of different samples. The electron beam apparatus 100 directs electrons onto the locations. The detector 144 or electron detection device 244 detects signal electrons emitted from the locations so as to perform the scans. By performing the scanning of the locations, scan data is generated. The scan data provides information about the location of structures on the locations.

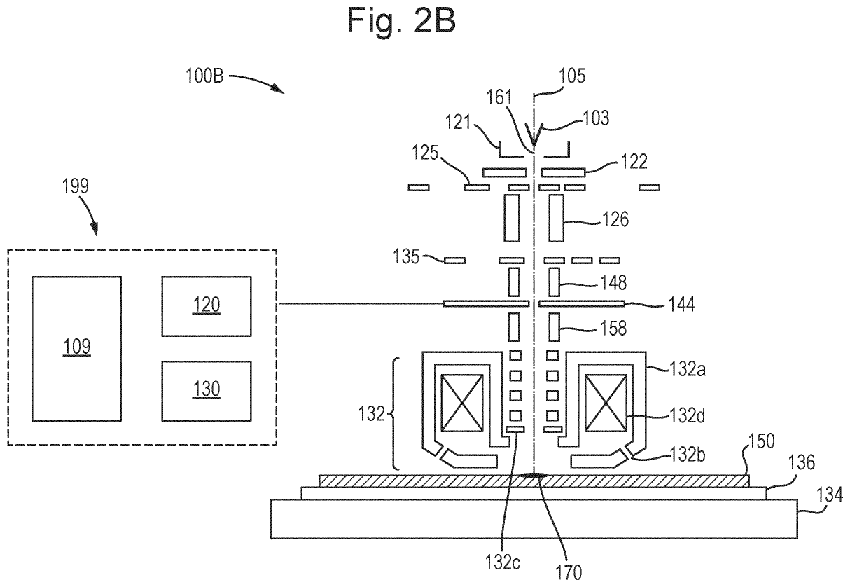

The scan data may be affected by distortion. The distortion may cause the scan data to indicate that a given structure is in a different location from where the structure is actually located on the location. Data corresponding to different locations within the location or field of view of the electron beam apparatus 100 may be distorted in different ways (e.g. in different directions or by different amounts). The distortion map indicating the distortion for different locations may be referred to as the grid distortion. FIG. 3 shows such a distortion map.

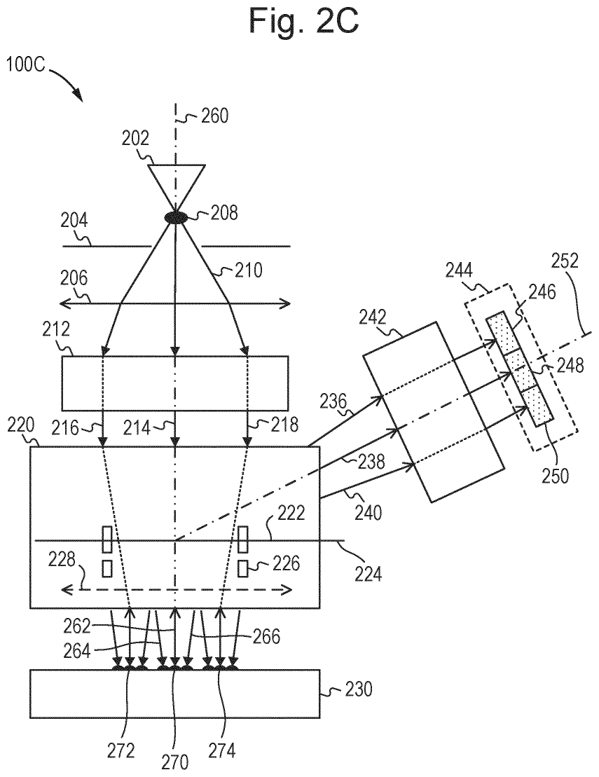

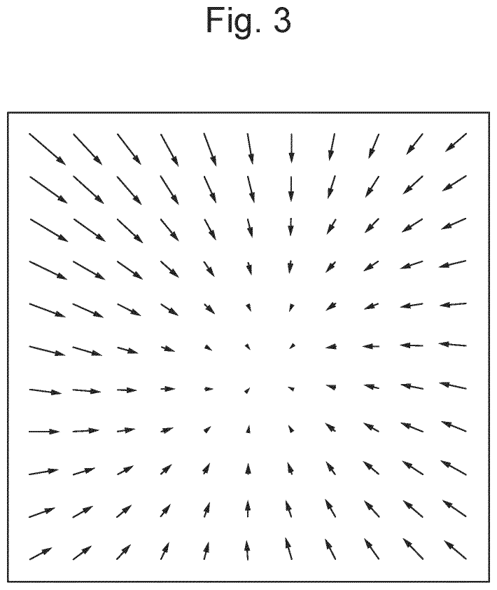

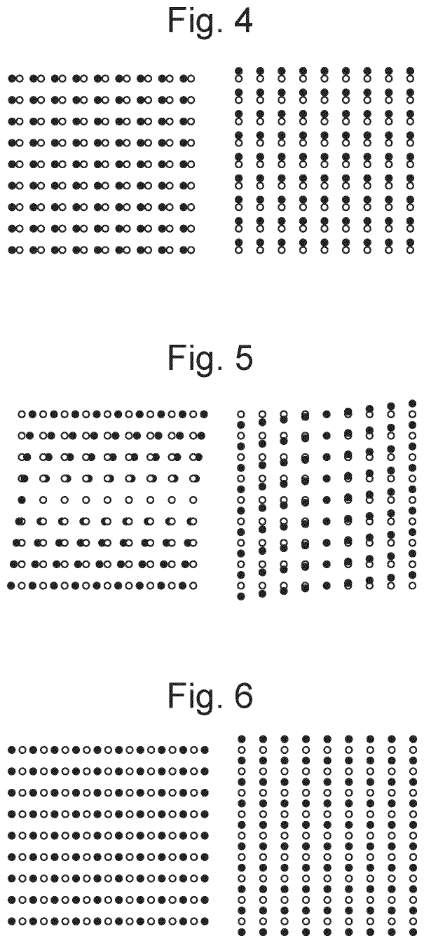

The grid distortion may comprise a translational component within the plane of the sample (i.e. the structure may be measured to be in a location that is shifted in the plane of the sample relative to its actual location). Translational distortion in the two directions within the plane are shown in FIG. 4. The distortion may comprise a rotational component (i.e. where the structures are imaged in an arrangement that is rotated about an axis perpendicular to the plane of the sample relative to their actual arrangement). Rotational distortion relative to the two directions within the plane are shown in FIG. 5. The distortion may comprise a magnification component (i.e. where distance between structures is measured as being greater than or smaller than the distance between the actual structures). Magnification distortion in the two direction within the plane are shown in FIG. 6. The translational, rotational and magnification grid distortion may be parameterised by six parameters including two translational parameters (in the X and Y directions), two rotational parameters and two magnification parameters (in the X and Y directions). Higher order grid distortions are possible in addition to, or instead of, the translational, rotational and magnification distortions. The overall grid distortion may be parameterised by more than six parameters, for example 20 parameters.

Part of the grid distortion may be caused by the scanning process. The distortion may be induced by the electron beam apparatus 100 itself. This may be referred to as SEM-induced grid distortion or electron-optical grid distortion. It is desirable to correct for the electron-optical grid distortion.

Some distortion of the scan data may be corrected for by using a model to correct the scan data based on information about the type of structures expected to be located on the sample. The structures that are intended to have been fabricated on the sample may be known. The intended structures and their intended locations on the sample may be known. This information can be used to correct some variations in electron-optical grid distortions between scans. Such a correction may be made using a polynomial fitting with a plurality of parameters (e.g. 20 parameters).

In an embodiment, a different fitting (a calculation of new values for the parameters) is made for different maps of intended structures and their intended locations. However, where the same arrangement of structures is intended for different locations, for example, the same fitting may be used. By using the same model, the risk of undesirable over correction is reduced. Any such over correction could result in real information about the actual locations of intended structures on the location being filtered out.

If the grid distortion is known, then the grid distortion may be corrected for. For example, FIG. 3 shows a diagram illustrating a grid distortion. Correction for the grid distortion may improve an SEM image.

In an embodiment the method comprises changing a setting of at least one electron-optical parameter of the electron beam apparatus 100 from location to location. In an embodiment the at least one electron-optical parameter of the electron beam apparatus 100 is changed from die-to-die. Additionally or alternatively, the at least one electron-optical parameter of the electron beam apparatus 100 is changed from location to location within one die. In an embodiment one or more electron-optical settings are recalibrated from location to location (e.g. from die-to-die). For example, in order to maintain the focus of the electron beam apparatus 100 on the sample, one or more electron-optical parameters may be adjusted for each location, in turn.

In an embodiment, the grid distortion may vary between different scans. Each image taken by the electron beam apparatus 100 may have its own grid distortion. In order to make the fitting for the model mentioned above, a fitting to calculate the values of the parameters may be performed for a plurality of images taken by the electron beam apparatus 100. The average values for the parameters across the images may be determined so as to determine an average fitting. This fitting may then be used from location-to-location, particularly when the locations have the same intended circuit fabricated on them.

In an embodiment the at least one electron-optical parameter affects an electron-optical grid distortion of the scan data. Each electron-optical parameter that is changed may affect the trajectory of electrons directed towards the sample by the electron beam apparatus 100. An electron-optical parameter that affects the trajectory of the electron beam may be expected to affect the electron-optical grid distortion.

In an embodiment the method comprises compensating for the electron-optical grid distortion, based on the changed setting of the at least one electron-optical parameter. By taking into account the way that the at least one electron-optical parameter is changed from location-to-location, the effect of that electron-optical parameter on the electron-optical grid distortion can be taken into account (i.e. corrected for).

When electron-optical parameters that affect the trajectory of the electron beam are changed from location-to-location, corresponding location-to-location variations in the electron-optical grid distortion may be expected. By compensating for the electron-optical grid distortion based on the changed setting of the at least one electron-optical parameter, the grid distortion may be better corrected for.

As mentioned above, a model may be used to correct for some electron-optical grid distortion by taking into account information about the intended structures on the sample. However, the same model is used across different locations so as to reduce the risk of over correction. By not changing the model, electron-optical grid distortion that changes from location-to-location is not taken into account and cannot be corrected for. By compensating for the location-specific electron-optical grid distortion, the distortion can be better corrected for.

There are different electron-optical parameters of the electron beam apparatus 100 that may be changed from location-to-location and may affect the electron-optical grid distortion. For example, in an embodiment the at least one electron-optical parameter comprises a voltage focus parameter. The voltage focus parameter contributes to determining a focus of the electron beam on the locations. In an embodiment the voltage focus parameter corresponds to an electric potential applied to a stage (e.g. the motorised stage 134) of the electron beam apparatus 100. In an embodiment the stage is configured to support the locations, for example to support the sample that comprises the locations.

In an embodiment the electron beam apparatus 100 comprises a voltage supply. The voltage supply is configured to apply an electric potential to the stage that supports the sample. In an embodiment the controller 109 is configured to control the voltage supply to apply an electric potential to the stage. By applying an electric potential to the stage, an electrostatic field may be generated between the stage and an electron-optical component of the electron beam apparatus 100 immediately up beam of the sample. In an embodiment the controller 109 is configured to control the electric potential applied to the stage so as to focus the electron beam on the sample. The electric potential applied to the stage affects the trajectory of the electrons of the electron beam. The electric potential applied to the stage affects the electron-optical grid distortion. By taking into account the effect of the voltage focus parameter on the grid distortion, the grid distortion may be better corrected for.

In an embodiment the at least one electron-optical parameter comprises a magnetic focus parameter. The magnetic focus parameter contributes to determining a focus of the electron beam on the locations, for example on the sample that comprises the locations. In an embodiment the magnetic focus parameter corresponds to an electric current that passes through a magnetic coil (e.g. the objective lens) of the electron beam apparatus 100. In an embodiment the electron beam apparatus 100 comprises one or more magnetic coils configured to generate a magnetic field. The magnetic field affects the trajectory of electrons of the electron beam. The magnetic field affects the electron-optical grid distortion.

In an embodiment the electron beam apparatus 100 comprises an electric current supply. The electric current supply is configured to pass an electric current through the magnetic coil. The electric current affects the trajectory of the electrons and affects the electron-optical grid distortion. By taking into account the effect of the magnetic focus parameter on the electron-optical grid distortion, the distortion may be better corrected for.

In an embodiment the at least one electron-optical parameter comprises a stigmator parameter. The stigmator parameter contributes to determining a cross-sectional shape of the electron beam. In an embodiment the stigmator parameter contributes to focussing the electron beam on the sample.

In an embodiment the stigmator parameter corresponds to an electric potential applied to at least one electrode of a stigmator multipole. In an embodiment the electron beam apparatus 100 comprises one or more multipoles. The multipole is configured to function as a stigmator configured to adjust a cross-sectional shape of the electron beam. For example, in an embodiment a stigmator multipole may comprise four poles (i.e. a quadrupole). Alternatively, the multipole may comprise two poles, six poles, eight poles or more. By applying different electric potentials to the different electrodes that form the multipole, the cross-sectional shape of the electron beam can be adjusted.

In an embodiment the electron beam apparatus 100 comprises a voltage supply. The voltage supply is configured to apply an electric potential to one or more of the electrodes of the multipole. In an embodiment a plurality of voltage supplies are provided to supply different electric potentials to different electrodes of the multipole. In an embodiment the controller 109 is configured to control the one or more voltage supplies so as to control the electric potentials applied to the electrodes of the stigmator multipole. The electric potential applied to one or more of the electrodes affects the trajectory of the electron beams and affects the electron-optical grid distortion. By taking into account the effect of the electric potential applied to one or more of the multipole electrodes, the distortion may be better corrected for.

In an embodiment the method is for correcting electron-optical-induced image-to-image variations in grid distortions, using a feedforward calibration.

In an embodiment the compensating is performed by controlling a deflector (e.g. the deflector 132c) of the electron beam apparatus 100. In an embodiment the controller 109 is configured to control the deflector so as to control a trajectory of the beam onto the locations. In an embodiment the controller 109 is configured to control the deflector based on the changed setting of the at least one electron-optical parameter.

Once the way at the electron-optical parameter affects the grid distortion is known, the deflector may be controlled appropriately so as to reduce the variation in distortion caused by the electron-optical parameter as it is changed. The compensation may be performed in hardware of the electron beam apparatus 100. In an embodiment the compensating is performed by controlling one or more other electron-optical components of the electron beam apparatus 100 that affect the trajectory of the electron beam.

It is not essential for the compensation to be performed in the hardware of the electron beam apparatus 100. In an alternative embodiment, the compensating is performed by correcting the scan data. In particular, the scan data may be generated by the electron beam apparatus 100 such that the scan data is affected by the electron-optical grid distortions that vary from location-to-location. The scan data may then be corrected based on the changed setting of the at least one electron-optical parameter. Once the effect of the electron-optical parameter on the grid distortion is known, the scan data can be corrected. In an embodiment the scan data is corrected in a post-processing step. The correction of the scan data may be performed using software. In an embodiment the controller 109 is configured to correct the scan data.

In an embodiment, the correction may be performed in both hardware and software. For example, in an embodiment the controller 109 is configured to control the deflector so as to affect the trajectory of the electron beams such that the scan data has reduced influence of the grid distortion. The controller 109 may be further configured to correct the generated scan data so as to further reduce the effect of the grid distortion.

In an embodiment a plurality of further electron-optical parameters (i.e. different from the at least one electron-optical parameter that is changed from location-to-location) of the electron beam apparatus 100 are kept substantially constant from location-to-location. For example, the electric potential applied to the most down beam electron-optical element of the electron beam apparatus 100 up beam of the stage may be kept substantially constant from location-to-location. Other further electron-optical parameters may also be kept the same between locations. Such further electron-optical parameters can induce electron-optical grid distortions. However, these grid distortions may be expected to be substantially the same between different locations. In an embodiment the grid distortions caused by these further electron-optical parameters may be corrected for.

For example, in an embodiment the deflector of the electron beam apparatus 100 is controlled so as to correct for the effect of electron-optical parameters of the electron beam apparatus 100 that are kept the same between different locations. In an embodiment, the effect of one or more electron-optical parameters that vary from location-to-location may be corrected for by controlling the deflector of the electron beam apparatus 100. The compensation (e.g. correction) for the electron-optical parameters that vary from location-to-location may lead to an adjustment of the calibration of the deflector that is used for correcting for the electron-optical parameters that are kept constant from location-to-location. In other words, the static electron-optical distortion and the dynamic electron-optical distortion (i.e. which varies from location-to-location) may be combined so as to control the deflector of the electron beam apparatus 100.

In an embodiment the method comprises measuring an effect of varying the at least one electron-optical parameter on the electron-optical grid distortion. As mentioned elsewhere, the at least one electron-optical parameter may relate to focus of the electron beam on the sample. In an embodiment an experiment is performed to measure the effect of varying the focus setting on the electron-optical grid distortion. Scans may be performed with one of the at least one electron-optical parameter set at different values (which may correspond to preferred focus settings) so as to measure the effect of the electron-optical parameter on the electron-optical grid distortion.

In an embodiment the effect of varying the voltage focus parameter, the magnetic focus parameter and/or the stigmator parameter on the translation, rotation and/or magnification of the grid distortion may be measured. In an embodiment, the measurements result in a multiple parameter model for each electron-optical parameter. The multiple parameter model may comprise, for example, six parameters corresponding to the translation, rotation and magnification of the SEM image. In an embodiment the results of the measurements are stored in a look-up table, for example. For example, the fix parameter models for each of the electron-optical parameter combinations may be stored in the look-up table. In an embodiment the controller 109 is configured to use the look-up table so as to determine an appropriate correction depending on the values of the at least one electron-optical parameter.

In an embodiment the method comprises interpolating between measurement results. For example, as mentioned elsewhere the measurements may be performed for preferred focus settings. There may be a continuous range of possible focus settings (e.g. possible values for the electron-optical parameters) between the measured settings. By interpolating between the results of the measuring, a model of how the at least one electron-optical parameter affects the grid distortion may be built up.

In an embodiment, the method comprises extrapolating from the results of the measuring.

It is not essential to perform the calibration experimentally in the electron beam apparatus 100. In an alternative embodiment, the compensating is performed using an electron-optical model. The electron-optical model is for predicting an effect of varying the at least one electron-optical parameter on the electron-optical grid distortion. For example, in an embodiment an electron-optical model is formed using simulations for tracking the trajectory of electrons of the electron beam directed by the electron beam apparatus 100.

In an embodiment a non-transitory computer readable medium stores instructions for a processor of a controller (e.g. the controller 109) to carry out a method as described above.

Exemplary embodiments of the present disclosure are set out in the following numbered clauses:
1. A method for operating a charged particle-optical apparatus, the method comprising:
   scanning, with the charged particle-optical apparatus, a sample comprising a series of locations with a charged particle beam, so as to generate scan data;
   changing a setting of at least one charged particle-optical parameter of the charged particle-optical apparatus from location to location, wherein the at least one charged particle-optical parameter affects a charged particle-optical grid distortion of the scan data; and
   compensating for the charged particle-optical grid distortion, based on the changed setting of the at least one charged particle-optical parameter.
2. The method of clause 1, wherein the at least one charged particle-optical parameter comprises a voltage focus parameter that contributes to determining a focus of the beam on the sample.
3. The method of clause 2, wherein the voltage focus parameter corresponds to an electric potential applied to a stage of the charged particle-optical apparatus configured to support the sample.
4. The method of any preceding clause, wherein the at least one charged particle-optical parameter comprises a magnetic focus parameter that contributes to determining a focus of the beam on the sample.
5. The method of clause 4, wherein the magnetic focus parameter corresponds to an electric current that passes through a magnetic coil of the charged particle-optical apparatus.
6. The method of any preceding clause, wherein the at least one charged particle-optical parameter comprises a stigmator parameter that contributes to determining a cross-sectional shape of the beam.
7. The method of clause 6, wherein the stigmator parameter corresponds to an electric potential applied to at least one electrode of a stigmator multipole.
8. The method of any preceding clause, wherein the compensating is performed by controlling a deflector of the charged particle-optical apparatus so as to control a trajectory of the beam onto the sample, based on the changed setting of the at least one charged particle-optical parameter.
9. The method of any preceding clause, wherein the compensating is performed by correcting the scan data, based on the changed setting of the at least one charged particle-optical parameter.
10. The method of any preceding clause, comprising measuring an effect of varying the at least one charged particle-optical parameter on the charged particle-optical grid distortion.
11. The method of clause 10, wherein the compensating is performed using results of the measuring.
12. The method of clause 11, comprising at least one of interpolation and extrapolation of the results of the measuring.
13. The method of any preceding clause, wherein the compensating is performed using a charged particle-optical model for predicting an effect of varying the at least one charged particle-optical parameter on the charged particle-optical grid distortion.
14. The method of any preceding clause, wherein settings of a plurality of further charged particle-optical parameters of the charged particle-optical apparatus are kept substantially constant from location to location.
15. The method of any preceding clause, comprising further compensating for the charged particle-optical grid distortion, based on information about target structures on the sample.
16. The method of clause 15, wherein the further compensating is performed using a model having the information about target structures on the locations as input, the same model being used for a plurality of the locations.
17. A charged particle-optical apparatus for scanning a sample comprising a series of locations with a charged particle beam, so as to generate scan data, the charged particle-optical apparatus comprising: a charged particle-optical device configured to direct a charged particle beam onto a series of locations, in turn;
   a detector configured to detect signal charged particles emitted from the locations, so as to generate scan data; and
   a controller configured to:
      change a setting of at least one charged particle-optical parameter of the charged particle-optical apparatus from location to location, wherein the at least one charged particle-optical parameter affects a charged particle-optical grid distortion of the scan data; and
      compensate for the charged particle-optical grid distortion, based on the changed setting of the at least one charged particle-optical parameter.
18. The charged particle-optical apparatus of clause 17, wherein the at least one charged particle-optical parameter comprises a voltage focus parameter that contributes to determining a focus of the beam on the sample.
19. The charged particle-optical apparatus of clause 18, comprising:
   a stage configured to support the sample; and
   a voltage supply configured to apply an electric potential to the stage, wherein the voltage focus parameter corresponds to the electric potential.
20. The charged particle-optical apparatus of any of clauses 17-19, wherein the at least one charged particle-optical parameter comprises a magnetic focus parameter that contributes to determining a focus of the beam on the sample.
21. The charged particle-optical apparatus of clause 20, comprising:
   a magnetic coil; and
   a current supply configured to pass an electric current through the magnetic coil, wherein the magnetic focus parameter corresponds to the electric current.
22. The charged particle-optical apparatus of any of clauses 17-21, wherein the at least one charged particle-optical parameter comprises a stigmator parameter that contributes to determining a cross-sectional shape of the beam.
23. The charged particle-optical apparatus of clause 22, comprising:
   a stigmator multipole; and
   a voltage supply configured to apply an electric potential to at least one electrode of the stigmator multipole, wherein the stigmator parameter corresponds to the electric potential.
24. The charged particle-optical apparatus of any of clauses 17-23, comprising:
   a deflector configured to control a trajectory of the beam onto the sample, wherein the controller is configured to compensate for the charged particle-optical grid distortion, by controlling the deflector based on the changed setting of the at least one charged particle-optical parameter.
25. The charged particle-optical apparatus of any of clauses 17-24, wherein the controller is configured to compensate for the charged particle-optical grid by correcting the scan data, based on the changed setting of the at least one charged particle-optical parameter.
26. A non-transitory computer readable medium that stores instructions for a processor of a controller to carry out a method of operating a charged particle-optical apparatus, the method comprising:
   scanning, with the charged particle-optical apparatus, a sample comprising a series of locations with a charged particle beam, so as to generate scan data;
   changing a setting of at least one charged particle-optical parameter of the charged particle-optical apparatus from location to location, wherein the at least one charged particle-optical parameter affects a charged particle-optical grid distortion of the scan data; and
   compensating for the charged particle-optical grid distortion, based on the changed setting of the at least one charged particle-optical parameter.
27. A method for operating a scanning electron microscope, SEM, the method comprising:
   scanning, with the SEM, a sample comprising a series of locations with an electron beam, so as to generate scan data;
   changing a setting of at least one electron-optical parameter of the SEM from location to location, wherein the at least one electron-optical parameter affects an electron-optical grid distortion of the scan data; and
   compensating for the electron-optical grid distortion, based on the changed setting of the at least one electron-optical parameter.
28. A scanning electron microscope, SEM, for scanning a sample comprising a series of locations with an electron beam, so as to generate scan data, the SEM comprising:
   an electron-optical device configured to direct an electron beam onto a sample comprising a series of locations, in turn;
   a detector configured to detect signal electrons emitted from the locations, so as to generate scan data; and
   a controller configured to:
      change a setting of at least one electron-optical parameter of the SEM from location to location, wherein the at least one electron-optical parameter affects an electron-optical grid distortion of the scan data; and
      compensate for the electron-optical grid distortion, based on the changed setting of the at least one electron-optical parameter.
29. A non-transitory computer readable medium that stores instructions for a processor of a controller to carry out a method of operating a scanning electron microscope, SEM, the method comprising:
   scanning, with the SEM, a sample comprising a series of locations with an electron beam, so as to generate scan data;
   changing a setting of at least one electron-optical parameter of the SEM from location to location, wherein the at least one electron-optical parameter affects an electron-optical grid distortion of the scan data; and
   compensating for the electron-optical grid distortion, based on the changed setting of the at least one electron-optical parameter.

A non-transitory computer readable medium may be provided that stores instructions for a processor of a controller (e.g., the controller 109 of FIG. 1) to carry out image assessment (e.g. metrology or inspection), image acquisition, activating charged-particle source, adjusting electrical excitation of stigmators, adjusting landing energy of electrons, adjusting objective lens excitation, adjusting secondary electron detector position and orientation, stage motion control, beam separator excitation, applying scan deflection voltages to beam deflectors, receiving and processing data associated with signal information from electron detectors, configuring an electrostatic element, detecting signal electrons, adjusting the control electrode potential, adjusting the voltages applied to the electron source, extractor electrode, and the sample, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A method for operating a charged particle-optical apparatus, the method comprising:
scanning, with the charged particle-optical apparatus, a sample comprising a series of locations with a charged particle beam, so as to generate scan data;
changing a setting of at least one charged particle-optical parameter of the charged particle-optical apparatus from location to location, wherein the at least one charged particle-optical parameter affects a charged particle-optical grid distortion of the scan data; and
compensating for the charged particle-optical grid distortion, based on the changed setting of the at least one charged particle-optical parameter.

2. The method of claim 1, wherein the at least one charged particle-optical parameter comprises a voltage focus parameter that contributes to determining a focus of the beam on the sample.

3. The method of claim 2, wherein the voltage focus parameter corresponds to an electric potential applied to a stage of the charged particle-optical apparatus configured to support the sample.

4. The method of claim 1, wherein the at least one charged particle-optical parameter comprises a magnetic focus parameter that contributes to determining a focus of the beam on the sample.

5. The method of claim 4, wherein the magnetic focus parameter corresponds to an electric current that passes through a magnetic coil of the charged particle-optical apparatus.

6. The method of claim 1, wherein the at least one charged particle-optical parameter comprises a stigmator parameter that contributes to determining a cross-sectional shape of the beam.

7. The method of claim 6, wherein the stigmator parameter corresponds to an electric potential applied to at least one electrode of a stigmator multipole.

8. The method of claim 1, wherein the compensating is performed by controlling a deflector of the charged particle-optical apparatus so as to control a trajectory of the beam onto the sample, based on the changed setting of the at least one charged particle-optical parameter.

9. The method of claim 1, wherein the compensating is performed by correcting the scan data, based on the changed setting of the at least one charged particle-optical parameter.

10. The method of claim 1, further comprising measuring an effect of varying the at least one charged particle-optical parameter on the charged particle-optical grid distortion.

11. The method of claim 10, wherein the compensating is performed using results of the measuring.

12. The method of claim 11, further comprising at least one of interpolation and extrapolation of the results of the measuring.

13. The method of claim 1, wherein the compensating is performed using a charged particle-optical model for predicting an effect of varying the at least one charged particle-optical parameter on the charged particle-optical grid distortion.

14. The method of claim 1, wherein settings of a plurality of further charged particle-optical parameters of the charged particle-optical apparatus are kept substantially constant from location to location.

15. The method of claim 1, further comprising further compensating for the charged particle-optical grid distortion, based on information about target structures on the sample.

16. A charged particle-optical apparatus for scanning a sample comprising a series of locations with a charged particle beam, so as to generate scan data, the charged particle-optical apparatus comprising:
a charged particle-optical device configured to direct a charged particle beam onto a series of locations, in turn;
a detector configured to detect signal charged particles emitted from the locations, so as to generate scan data; and
a controller configured to:
change a setting of at least one charged particle-optical parameter of the charged particle-optical apparatus from location to location, wherein the at least one charged particle-optical parameter affects a charged particle-optical grid distortion of the scan data; and
compensate for the charged particle-optical grid distortion, based on the changed setting of the at least one charged particle-optical parameter.

17. The charged particle-optical apparatus of claim 16, wherein the at least one charged particle-optical parameter comprises a voltage focus parameter that contributes to determining a focus of the beam on the sample.

18. The charged particle-optical apparatus of claim 17, comprising:
a stage configured to support the sample; and
a voltage supply configured to apply an electric potential to the stage, wherein the voltage focus parameter corresponds to the electric potential.

19. The charged particle-optical apparatus of claim 16, wherein the at least one charged particle-optical parameter comprises a magnetic focus parameter that contributes to determining a focus of the beam on the sample.

20. A non-transitory computer readable medium that stores instructions that are executable by one or more processors of a charged particle-optical apparatus to cause the charged particle-optical apparatus to perform operations comprising:
scanning a sample comprising a series of locations with a charged particle beam, so as to generate scan data;
changing a setting of at least one charged particle-optical parameter of the charged particle-optical apparatus from location to location, wherein the at least one charged particle-optical parameter affects a charged particle-optical grid distortion of the scan data; and
compensating for the charged particle-optical grid distortion, based on the changed setting of the at least one charged particle-optical parameter.
